(19) United States
(12) Patent Application Publication
(10) Pub. No.: US 2011/0043081 A1
(43) Pub. Date: Feb. 24, 2011

(54) PIEZOELECTRIC ELECTROSTRICTIVE COMPOSITION APPARATUS AND METHOD

(76) Inventors: Ahmad Safari, Green Brook, NJ (US); Piyalak Ngernchuklin, Khlong Luang (TH)

Correspondence Address: GREENBERG TRAURIG, LLP, 200 PARK AVE., P.O. BOX 677, FLORHAM PARK, NJ, 07932, US

(21) Appl. No.: 12/861,307

(22) Filed: Aug. 23, 2010

Related U.S. Application Data
(60) Provisional application No. 61/236,003, filed on Aug. 21, 2009.

(51) Int. Cl. H01L 41/18

(52) U.S. Cl. 310/367

(57) ABSTRACT

An actuator apparatus and method may comprise a monolithic construction of piezoelectric effect and electrostrictive effect materials. The actuator may comprise at least one piezoelectric material layer and at least one electrostrictive material layer. The at least one piezoelectric material layer may comprise a plurality of piezoelectric layers or the at least one electrostrictive layer may comprise a plurality of electrostrictive layers. The actuator may comprise the monolithic construction of piezoelectric and electrostrictive materials having a perimeter; a rigid plate; an adhesion mechanism holding the perimeter to the rigid plate preventing movement of the perimeter with respect to the rigid plate. The monolithic construction may be formed by co-sintering and co-pressing the piezoelectric effect material with the electrostrictive effect material. The actuator could comprise PMN/PT-65/35 piezoelectric and PMN/PT-90/10 electrostrictive. The actuator could be included in, such as, a nano-positioner, a valve actuator, an adaptive optical mounting, or a micropump.

### RELATED APPLICATIONS

The present application claims priority to U.S. Provisional Patent Application Ser. No. 61/236,003, entitled PIEZOELECTRIC ELECTROSTRICTIVE COMPOSITION DEVICE AND METHOD, filed on Aug. 21, 2009, the disclosure of which is hereby incorporated by reference.

### BACKGROUND

Piezoelectric and electrostrictive materials are used in industrial and consumer applications for in the case of the former creating an electric field in the presence of mechanical tension or, in the case of both, conversely for changing their geometry in the presence of an electric field. Actuators are devices made from such materials that are used to provide, e.g., displacement of loads in the tenths of Newtons (N), with sub-mm accuracies in displacement.

The piezoelectric effect is understood as the linear electromechanical interaction between the mechanical and the electrical state, e.g., in crystalline materials with no inversion symmetry. The piezoelectric effect is a reversible process in that materials exhibiting a direct piezoelectric effect (the internal generation of electrical charge resulting from an applied mechanical force) also exhibit the reverse piezoelectric effect (the internal generation of a mechanical force resulting from an applied electrical field). For example, lead zirconate titanate (“PZT”) crystals will generate measurable piezoelectricity when the static structure of the material is deformed to about 0.1% of the original dimension. Conversely, PZT crystals will change about 0.1% of their static dimension when an external electric field is applied to the material.

Electrostriction is a property of all dielectric materials, and is caused by the presence of randomly-aligned electrical domains within the material. When an electric field is applied to the dielectric, the opposite sides of the domains become differently charged and attract each other, thereby reducing material thickness in the direction of the applied field (and increasing thickness in the orthogonal directions due to Poisson's ratio). The resulting strain (ratio of deformation to the original dimension) is proportional to the square of the polarization. Reversal of the electric field, however, does not reverse the direction of the deformation.

More formally, the electrostriction coefficient is a fourth rank tensor (Quᵢⱼₖₗ), relating second order strain (xᵢⱼ) and first order polarization tensors (Pₖ, Pₗ), such that:

Iᵢⱼ=Qᵢⱼₖₗ×Pₖ×Pₗ

The related piezoelectric effect occurs only in a particular class of dielectrics. Electrostriction applies to all crystal symmetries, while the piezoelectric effect only applies to the 20 piezoelectric point groups. Electrostriction is a quadratic effect, unlike piezoelectricity, which is a linear effect. In addition, as noted above, and unlike piezoelectricity, electrostriction cannot be reversed, i.e., deformation will not induce an electric field.

### SUMMARY

According to aspects of an embodiment of the disclosed subject matter, a “Bi-Layer Piezoelectric/Electrostrictive (P/E) Dome Unimorph” [BIPEDU] is disclosed. Such an actuator may be composed of piezoelectric layer(s), such as, a lead magnesium niobate-lead titanate (“PMN/PT”)-65/35 and an electrostrictive layer(s), such as PMN/PT-90/10. Such an actuator may be manufactured by co-pressing and co-sintering these layers together as a monolithic construction. Internal stress can be generated after fabrication due, e.g., to thermal expansion mismatch of the two materials which can result in a domed shape and enhanced actuation performance. The dome may be attached to a rigid substrate, such as a rigid plate that can be used to prevent the movement of the perimeter of the base of the dome, which can result in a dramatic improvement of the performance of the actuator.

Such an actuator may be used as a component in electronic devices requiring a large and precise displacement, moderate load bearing and low electrical loss such as micropositioners, noise and vibration canceling devices, micropumps, deformable mirrors, loudspeakers, laser and other light deflectors, damping devices, auto focus cameras and, in high reliability applications requiring reasonable actuation performance like precision machining, optics, astronomy and fluid control.

According to aspects of an embodiment of the disclosed subject matter, an actuator is provided that can have a significant amplification of displacement, a narrower displacement hysteresis loop and reduced electromechanical loss, e.g., due to the monolithic combination of materials with piezoelectric and the electrostrictive effects. According to other aspects of embodiments of the disclosed subject matter a faster, simpler and cheaper manufacturing process is an advantage of the construction of the disclosed actuator. An actuator is provided which may have a plurality of piezoelectric material layers, a plurality of electrostrictive material layers, and means to prevent the movement of the perimeter, such as, the circumference of a dome constructed of the materials according to aspects of an embodiment of the disclosed subject matter. In such an actuator a plurality of piezoelectric layers can consist of one layer and the plurality of electrostrictive layers consist of one layer. Such an actuator may also have a plurality of piezoelectric material layers, and means to prevent the movement of the perimeter or the circumference, e.g., of a dome forming the actuator. Alternatively there may be a plurality of electrostrictive layers, and means to prevent the movement of the perimeter or the circumference of the dome. Such an actuator may be formed by co sintering and co pressing a plurality of layers as a monolithic construction. The actuator may be made with PMN/PT-65/35 piezoelectric material and PMN/PT-90/10 electrostrictive material.

### BRIEF DESCRIPTION OF THE DRAWINGS

FIG. 1 shows a schematic of a Bi-Layer Piezoelectric/Electrostrictive (P/E) Dome Unimorph (BIPEDU) according to aspects of an embodiment of the disclosed subject matter;

FIG. 2a illustrates graphically displacement under an electric field of 10 kV/cm of a dome actuator and BIPEDU with a P/E 6/4 ratio;

FIG. 2b illustrates graphically displacement under an electric field of 10 kV/cm of dome actuator and a BIPEDU with a P/E 7/3 ratio;

FIG. 2c illustrates graphically displacement under an electric field of 10 kV/cm of a dome actuator and a BIPEDU with a P/E 8/2 ratio;

FIG. 3a illustrates graphically displacement versus load of a BIPEDU dome actuator at P/E 6/4, 7/3 and 8/2 volume ratios under an electric field 10 kV/cm;

FIG. 3b illustrates graphically displacement versus load of a BIPEDU at P/E 6/4, 7/3 and 8/2 volume ratios under an electric field 10 kV/cm;

FIG. 4 illustrates graphically cyclic displacement to load behavior of BIPEDU at P/E 6/4 volume ratio; and,

### DETAILED DESCRIPTION OF THE INVENTION

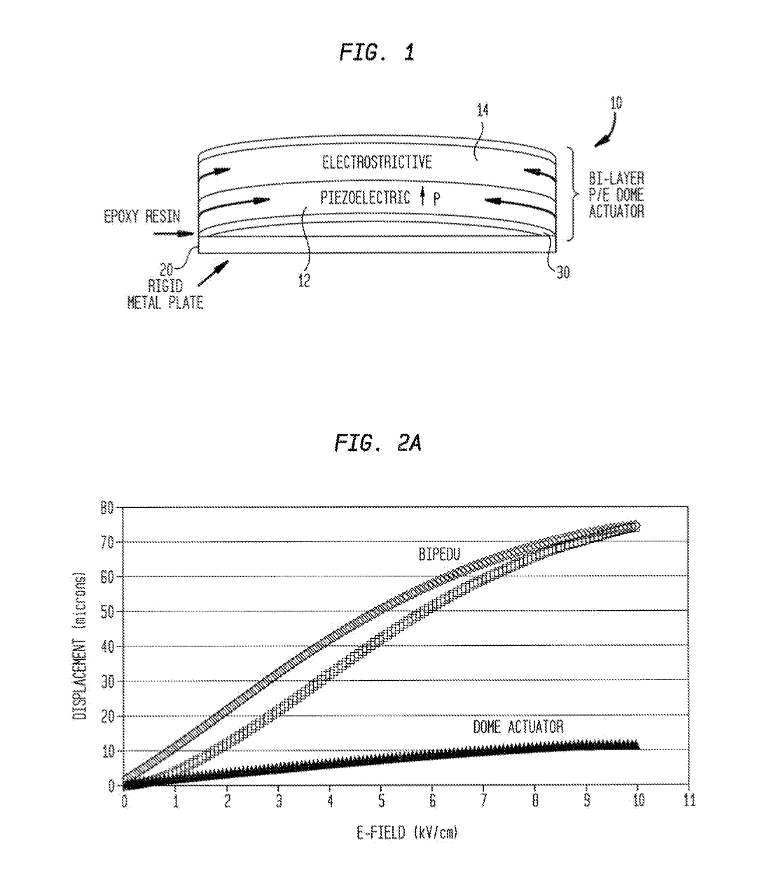

Applicants have determined that an improved performance bi-layer actuator 10, such as is illustrated schematically in FIG. 1, can be fabricated from materials with different thermal expansion coefficients (TEC) EC) which create internal stress after manufacturing. This improves the mechanical performance and can shape the device 10 as a dome. The manufacturing process for use of piezoelectric and electrostrictive materials is generally known as sintering. A “green body” can be formed by pressing the powder that is generally produced by spray drying a slurry comprising the piezoelectric or electrostrictive material, binders and liquid. The body can then heated to a low temperature, to burn off the binder, followed by sintering at a high temperature beyond the melting point to fuse particles together. Sintering can be done with pressure (hot pressing) or without.

Turning now to FIG. 1, there is shown a BIPEDU 10, i.e., a bi-layer P/E unimorph dome composed of piezoelectric material 12, such as PMN/PT-65/35 and electrostrictive material 14, such as, PMN/PT-90/10 layers as the electrically active elements. Internal stress within the element 10 can be generated during fabrication due to the different thermal expansion coefficient (TEC) of the two materials 12, 14. The dome bi-Layer actuator 10 has its perimeter firmly attached to a rigid plate 20 which can improve dramatically the actuation performances under an external E-field. During the above mentioned sintering process in a boundary between the piezoelectric layer 12 and the electrostrictive layer 14 the piezoelectric layer 12 and electrostrictive layer 14 can be caused to fuse into a monolithic structure that assists in bonding the piezoelectric layer 12 and electrostrictive layer 14 together.

In a preferred embodiment epoxy resin 30 can be applied around the circumference of the actuator 10 as shown schematically in FIG. 1. That can result in a dramatic improvement of the actuation performance.

The device 10 can be manufactured using, e.g., a conventional dry pressing method using fewer steps for the bi-layer green ceramic preparation. This process can be faster and cost less. Piezoelectric and electrostrictive powders can be individually dry-pressed on top of each other at pressure such as 86, 114 and 229 MPa into pellets with 14.7 mm diameter and 1.15-1.3 mm thickness using a uni-axial hydraulic machine. Once the dimensions and masses of green pellets are recorded, the binder removal and pre-sintering can be performed at 550° C. for 3 hours and 780° C. for 1 hour, respectively. Then the same parameters can be recorded before and after the sintering step. The pellets can then be sintered in a closed alumina crucible with 3 grams of PbZrO₃ source, at 1150, 1200 and 1250° C. for 1 hour. The heating and cooling rate can be set at 3° C./min during sintering. A monolithic layer containing both the piezoelectric material and the electrostrictive material forms at the boundary of the two and enhances adhesion between the respective layers.

The BIPEDU 10 can be used as an actuator through the converse piezoelectric effect where an electric field is applied across the actuator 10 to generate strain and displacement in the micron-scale range. When an electric field is applied in the same direction as poling, both the piezoelectric and electrostrictive layers contract and the center of the element 10 moves up, as illustrated schematically in FIG. 1. The metal plate 20 attached to the bi-layer dome actuator 10 can act as a support which provides more force to push up the bi-layer P/E element 10 and can thus generate additional displacement and strain amplification. The monolithic combination of materials of the piezoelectric layer 12 and electrostrictive layer 14, within the boundary layer between the piezoelectric layer 12 and electrostrictive layer 14, can reduce electromechanical loss and narrow displacement of the hysteresis loop. By using the two active piezoelectric and electrostrictive materials, the sum of the transverse piezoelectric coefficient (d₃₃) effective can be converted to additional displacement in the longitudinal direction (toward the top of the page in the illustration of FIG. 1) under an applied electric field.

The enhanced actuation performance of the BIPEDU 10 makes it suitable for many applications including but not limited to nanopositioning, active and adaptive optics, vibration cancellation, pneumatic valves, micropumps and laser tuning which requires high resolution and high precision displacement.

Aspects of embodiments of the disclosed subject matter may be described more fully by way of the following non-limiting examples.

### Example 1

In an embodiment two different compositions of lead magnesium niobate-lead titanate (PMN/PT) were used to form the bi-layer dome actuators 10. Piezoelectric PMN/PT-65/35 and electrostrictive PMN/PT-90/10 powders were mixed with a 20 wt % polyvinyl alcohol (PVA) solution at a 6 wt % concentration separately, and then heated in an oven for 15 minutes at 120° C., ground and sieved to obtain uniformly fine powder. Bilayer actuator 10 structures with various volume ratios of piezoelectric and electrostrictive powders were prepared by uniaxial co-pressing at 86 MPa pressure in a die with the diameter of 15 mm. The thickness of the pressed bi-layer sample was about 1.2 mm. After heating for binder removal at 550° C. for 3 hours, the bi-layers were co-sintered at 1200° C. with the dwell time of 1 hour. An excess Pb source was placed in the crucible to suppress Pb losses during sintering. The samples were curved slightly after sintering with dome height in the range of 0.3-0.45 mm. The concave side (piezoelectric layer 12) of the bi-layer P/E actuator 10 was then slightly polished in the edge area with SiC sandpaper (1200 grit) to create a contact ring area where the metal plate was attached to the bi-layer P/E dome actuator, e.g., with epoxy resin.

### Example 2

In an embodiment of the actuator device 10, rigid metal plates 20 (76 pm thick stainless steel) with essentially identical diameter to the bi-layer P/E actuators 10 were prepared using a punching tool. To attach the bi-layer structure 10 and metal plate 20, the epoxy resin 30 (available from Emerson and Cuming Inc., Billerica, Mass., under the product designation of Eccobond 15 LV and Catalyst 15 LV) was applied around the polished circumferential area, aligning the whole assembly 10 in a fixture used to attach the element 10 to the plate 20. In this example, the Eccobond/Catalyst mixing ratio of 3/1 (by weight) was used to obtain a bonding layer with moderate stiffness. The thickness of the cured epoxy was about 20 μm. Then the fixture was placed into the oven at 65° C. for 3 hours to harden the epoxy resin. The device 10 can be embodied in a miniature actuator 10 (such as, having a 10 mm diameter and 1.2 mm thickness) with a moderate displacement (up to 70 microns @ 1000 V) and moderate load (up to 10 N @ 1000 V) that is well suited for nanopositioning/high speed switching, miniature pneumatic and hydraulic valves, micropumps, laser tuning and active and adaptive optic and vibration cancellation applications.

### Example 3

The device 10 described in example 2 was further tested by electroding it with fire-on silver paste and heat treated at 550° C. for 15 minutes. Poling was carried out with a 25 kV/cm electric field strength in a heated silicone oil bath for 10 minutes at 150° C., followed by a cool-down to room temperature under the same poling field strength. The electromechanical properties of the bi-layer P/E monolithic composites 10 were characterized after 1 day of aging at room temperature. The effective piezoelectric coefficient d₃₃ effective of the poled actuator 10 was measured directly with a Berlincourt d₃₃-meter piezometer at 100 Hz. The room temperature dielectric constant and loss tangent of the samples were measured at 1 kHz using an HP 4194A impedance/gain-phase analyzer (available from Hewlett Packard, Palo Alto, Calif., under the model number HP 4194A). The field-induced displacement was also investigated by a photonic sensor (available from MTI instruments, Latham, N.Y., under the model number MTI 2000).

The electric field induced displacements of actuators 10 were determined using a DC unipolar wave form, which was coupled to a high voltage displacement fixture (HVDF) provided by Radiant Technologies Inc. of New Mexico, U.S.A., under the name High Voltage Interface). A photonic fiber optic sensor probe (photonic sensor, model number MTI 2000) was used to measure the displacement of the actuator 10 under an applied field. Specifically, the BIPEDU actuator 10 was placed between two copper electrodes of the HVDF and loaded with 0.5 N forces which were exerted by a top copper electrode. Also the load-displacement behavior of the actuator 10 was investigated by placing the external load on top of the upper copper electrode.

The electromechanical properties (d₃₃ effective, relative permittivity (K), tan 8 and displacement) of bilayer P/E component(s) 10 (before being attached to a metal plate) with P/E 6/4, 7/3 and 8/2 ratios were recorded. The displacement of a sample BIPEDU 10 is shown in Table 1.

TABLE 1

| | d₃₃ eff | | | Displacement (μm) | Displacement (μm) |
|---|---|---|---|---|---|
| Designation | (pC/N) | K | % tan 6 | Dome P/E component | BIPEDIJ |
| P/E: 6/4 | 372 ± 22 | 4,370 ± 230 | −2.26 ± 0.04 | 10.38 ± 0.48 | 73 ± 1.98 |
| P/E: 7/3 | 520 ± 26 | 3,715 ± 70 | 1.93 ± 0.14 | 8 ± 0.40 | 69 ± 4.75 |
| P/E: 8/2 | 550 ± 10 | 3,370 ± 100 | 1.72 ± 0.07 | 5.48 ± 0.28 | 65 ± 3.89 |

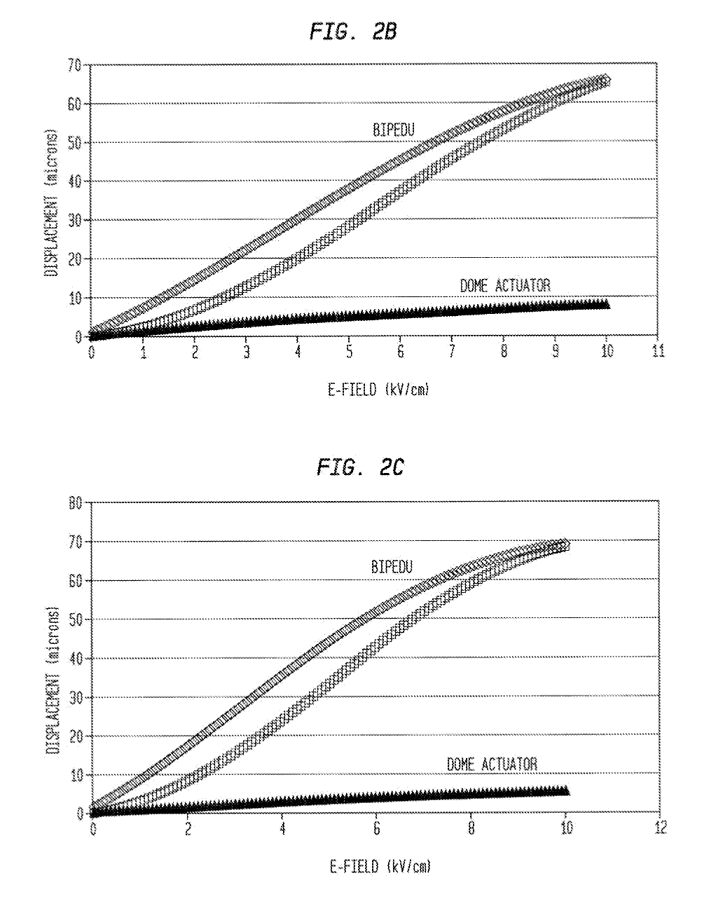

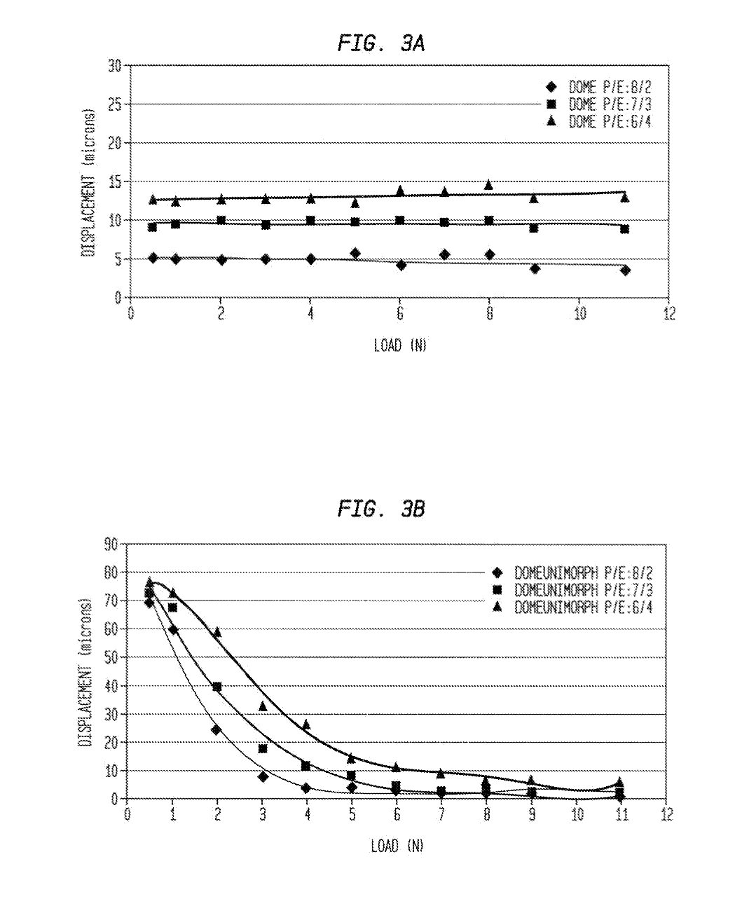

The comparison of the actuation performance between bi-layer P/E Dome acutaors which were not attached to a rigid metal plate, as noted above, and BIPEDU actuators 10 at P/E 6/4, 7/3 and 8/2 volume ratios are depicted in FIGS. 2a-2c respectively. A dc electric field 10 kV/cm was applied to the comparison dome actuators and BIPEDU actuators 10 and the displacement signals at the center of the dome were detected by the above mentioned photonic sensor. The measured BIPEDU displacement of 65-73 μm was 7-12 times higher than that of the comparison bi-layer P/E dome actuator (5-11 μm). The displacements vs. load results are shown in FIGS. 3a-b for both comparison bi-layer P/E dome actuators (FIG. 3a) and BIPEDU actuators 10 (FIG. 3b). The dome actuators 10 showed that they can tolerate load over 10 N. The excellent performance of the dome actuator components under the applied load is due to the dome geometry and also due to free movement of the actuator in the circular base plane (no adhesive was applied in this stage). On the other hand, the BIPEDU actuator 10 displacement decreased as the applied load was increased and showed the displacement in the range of 3-6 microns at 11 N. This is because the bi-layer actuators were glued to metal plate with resulting restraint in the movement of the overall actuator 10 in the plane under applied load.

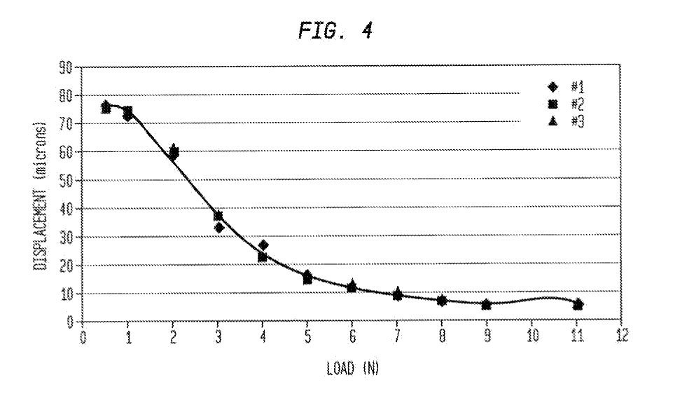

FIG. 4 depicts cyclic displacement-load behavior of representative BIPEDU's 10 with a P/E 6/4 ratio. In this experiment, three cycles of load-displacement data were consecutively recorded from 0.5-11 N with 1 N intervals and an E-field applied at 10 kV/cm. The results showed a precise load-displacement trend in each cycle.

It is understood that one skilled in the art would be able to comprehend additional embodiments based on the teaching herein, which embodiments are intended to be included in this application.

1. An actuator comprising;
a monolithic construction of piezoelectric effect material and electrostrictive effect material in a boundary between the piezoelectric effect material and the electrostrictive material.

2. The actuator of claim 1 further comprising:
at least one piezoelectric material layer and at least one electrostrictive material layer.

3. The actuator of claim 2 further comprising:
the at least one piezoelectric material layer comprising a plurality of piezoelectric layers.

4. The actuator of claim 2 further comprising:
the at least one electrostrictive layer comprising a plurality of electrostrictive layers.

5. The actuator of claim 1 further comprising:
the piezoelectric material and electrostrictive material forming a dome having a perimeter;
a rigid plate;
an adhesion mechanism holding the perimeter to the rigid plate preventing movement of the perimeter with respect to the rigid plate.

6. The actuator of claim 2 further comprising:
the piezoelectric material and electrostrictive material forming a dome having a perimeter;
a rigid plate;
an adhesion mechanism holding the perimeter to the rigid plate preventing movement of the perimeter with respect to the rigid plate.

7. The actuator of claim 3 further comprising:
the piezoelectric material and electrostrictive material forming a dome having a perimeter;
a rigid plate;
an adhesion mechanism holding the perimeter to the rigid plate preventing movement of the perimeter with respect to the rigid plate.

8. The actuator of claim 4 further comprising:
the piezoelectric material and electrostrictive material forming a dome having a perimeter;
a rigid plate;
an adhesion mechanism holding the perimeter to the rigid plate preventing movement of the perimeter with respect to the rigid plate.

9. The actuator of claim 1 further comprising:
the monolithic construction is formed by co-sintering and co-pressing the piezoelectric effect material with the electrostrictive effect material.

10. The actuator of claim 2 further comprising:
the monolithic construction is formed by co-sintering and co-pressing the at least one piezoelectric effect material layer and the electrostrictive effect material layer.

11. The actuator of claim 9 further comprising:
the actuator forming the shape of a dome.

12. The actuator of claim 10 further comprising:
the actuator forming the shape of a dome.

13. The actuator of claim 1 further comprising:
the piezoelectric material comprising PMN/PT-65/35 and the electrostrictive material comprising PMN/PT-90/10.

14. The actuator of claim 2 further comprising:
the piezoelectric material comprising PMN/PT-65/35 and the electrostrictive material comprising PMN/PT-90/10.

15. The actuator of claim 9 further comprising:
the piezoelectric material comprising PMN/PT-65/35 and the electrostrictive material comprising PMN/PT-90110.

16. The actuator of claim 10 further comprising:
the piezoelectric material comprising PMN/PT-65/35 and the electrostrictive material comprising PMN/PT-90/10.

17. An apparatus comprising:
a nano-positioning element as set forth in claim 1.

18. An apparatus comprising:
a valve actuator comprising:
an actuator as set forth in claim 1

19. An apparatus comprising:
an adaptive optical mounting comprising:
an actuator as set forth in 1.

20. An apparatus comprising:
a micropump comprising:
an actuator as set forth in claim 1.
